(19) United States
(12) Patent Application Publication
(10) Pub. No.: US 2007/0148863 A1
(43) Pub. Date: Jun. 28, 2007

(54) Method for fabricating semiconductor device

(75) Inventors: Dae-Young Seo, Kyoungki-do (KR); Ki-Ro Hong, Kyoungki-do (KR); Do-Hyung Kim, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor, Inc.

(21) Appl. No.: 11/440,864

(22) Filed: May 24, 2006

(30) Foreign Application Priority Data
Dec. 28, 2005 (KR) 2005-0132569

(51) Int. Cl. H01L 21/336

(52) U.S. Cl. 438/257; 438/396; 257/E21.613

(57) ABSTRACT

A method for fabricating a semiconductor device is provided. The method includes forming a plurality of gate lines over a substrate, wherein the substrate is defined into a cell region and a peripheral region, forming a gate spacer layer over the gate lines, the gate spacer layer including a buffer layer, an insulation layer, and a barrier layer, forming a mask pattern over the barrier layer in a manner to cover the cell region and open the peripheral region, performing an anisotropic etching method on the gate spacer layer using the mask pattern as an etch mask to form gate spacers on sidewalls of the gate lines in the peripheral region, performing an ion implantation process to form source/drain regions in the peripheral region, and simultaneously removing the mask pattern and the barrier layer.

### FIELD OF THE INVENTION

The present invention relates to a method for fabricating a semiconductor device; and, more particularly, to a method for fabricating a semiconductor device.

### DESCRIPTION OF RELATED ARTS

Generally, when an electric field is strongly formed on the edge of a drain region of a transistor in a dynamic random access memory (DRAM), hot carriers increase, and thus, device characteristics deteriorate. To reduce the deterioration of the device characteristics, gate spacers including an insulation material are formed on sidewalls of a gate electrode.

For example, after a gate electrode is formed during a DRAM fabrication process, gate spacers including oxide/nitride are formed in a cell region, and other gate spacers including oxide/nitride/oxide are formed in a peripheral region.

FIGS. 1A and 1B are cross-sectional views illustrating a conventional method for fabricating a semiconductor device.

As shown in FIG. 1A, a gate oxide layer 12 is formed over a substrate 11, wherein the substrate 11 is defined into a cell region and a peripheral region, and gate electrode 13 and a gate hard mask 14 are formed over the gate oxide layer 12. Then, a plurality of gate lines are formed through a gate patterning process. Herein, the gate lines are formed in both the cell region and the peripheral region.

A first silicon oxide layer 15 and a silicon nitride layer 16 are formed over the gate lines and the substrate 11. Then, a second silicon oxide layer 17 is formed over the silicon nitride layer 16. Herein, the silicon nitride layer 16 is formed to provide insulation between the gate lines and contact plugs.

Although not illustrated, a photoresist layer is formed over the second silicon oxide layer 17, and then a photo-exposure and developing process is performed to pattern the photoresist layer to thereby form a first mask layer 18 opening the peripheral region. Herein, the first mask layer 18 is formed to cover the entire cell region and expose the peripheral region.

Portions of the first silicon oxide layer 15, the second silicon oxide layer 17, and the silicon nitride layer 16, formed in the peripheral region and exposed by the first mask layer 18, are etched by employing an anisotropic etching method to form gate spacers in a triple-layered structure. Herein, each of the gate spacers in the triple-layered structure includes a dome-type spacer which includes a patterned second silicon oxide layer 17A and L-shaped spacers which include a patterned silicon nitride layer 16A and a patterned first silicon oxide layer 15A.

An ion implantation process is performed to form source/drain regions 19 of a transistor in the peripheral region. At this time, the first mask layer 18 and the patterned second silicon oxide layer 17A function as an ion implantation barrier.

As shown in FIG. 1B, the first mask layer 18 is removed, and then, a photoresist layer (not shown) is formed over the resultant substrate structure. Then, a photo-exposure and developing process is performed on the photoresist layer to form a second mask layer 20 opening the cell region. Herein, the second mask layer 20 is formed to expose the cell region and cover the peripheral region. Next, a wet etching process is performed to remove the second silicon oxide layer 17 in the cell region.

However, in the conventional method, the silicon nitride layer and the first silicon oxide layer are often damaged, as shown with reference denotations X and Y, by a wet chemical used in the wet etching process for removing the remaining second silicon oxide layer in the cell region. When the silicon nitride layer becomes damaged by the wet etching process, the silicon nitride layer cannot perform as a barrier, and generally results in a generation of bridges between the gate lines and the contact plugs.

Furthermore, as the design rule has decreased, difficulties in removing the second silicon oxide layer between gate lines may increase.

### SUMMARY OF THE INVENTION

It is, therefore, an object of the present invention to provide a method for fabricating a semiconductor device which can reduce damage to a bottom insulation layer of a gate spacer during a wet etching process in a cell region.

In accordance with an aspect of the present invention, there is provided a method for fabricating a semiconductor device, including: forming a plurality of gate lines over a substrate, wherein the substrate is defined into a cell region and a peripheral region; forming a gate spacer layer over the gate lines, the gate spacer layer including a buffer layer, an insulation layer, and a barrier layer; forming a mask pattern over the barrier layer in a manner to cover the cell region and open the peripheral region; performing an anisotropic etching method on the gate spacer layer using the mask pattern as an etch mask to form gate spacers on sidewalls of the gate lines in the peripheral region; performing an ion implantation process to form source/drain regions in the peripheral region; and simultaneously removing the mask pattern and the barrier layer.

In accordance with another aspect of the present invention, there is provided a method for fabricating a semiconductor device, including: forming a plurality of gate lines over a substrate, wherein the substrate is defined into a cell region and a peripheral region; forming a silicon oxide layer, a silicon nitride layer, and an amorphous carbon layer over the gate lines; forming a photoresist pattern over the amorphous carbon layer in a manner to cover the cell region and open the peripheral region; etching the silicon oxide layer, the silicon nitride layer, and the amorphous carbon layer with an anisotropic etching method to form gate spacers on sidewalls of the gate lines in the peripheral region; performing an ion implantation process to form source/drain regions in the peripheral region; and simultaneously removing the mask pattern and the amorphous carbon layer.

### BRIEF DESCRIPTION OF THE DRAWINGS

The above and other objects and features of the present invention will become better understood with respect to the following description of the specific embodiments given in conjunction with the accompanying drawings, in which:

FIGS. 1A and 1B are cross-sectional views illustrating a conventional method for fabricating a semiconductor device; and

FIGS. 2A to 2C are cross-sectional views illustrating a method for fabricating a semiconductor device in accordance with a specific embodiment of the present invention.

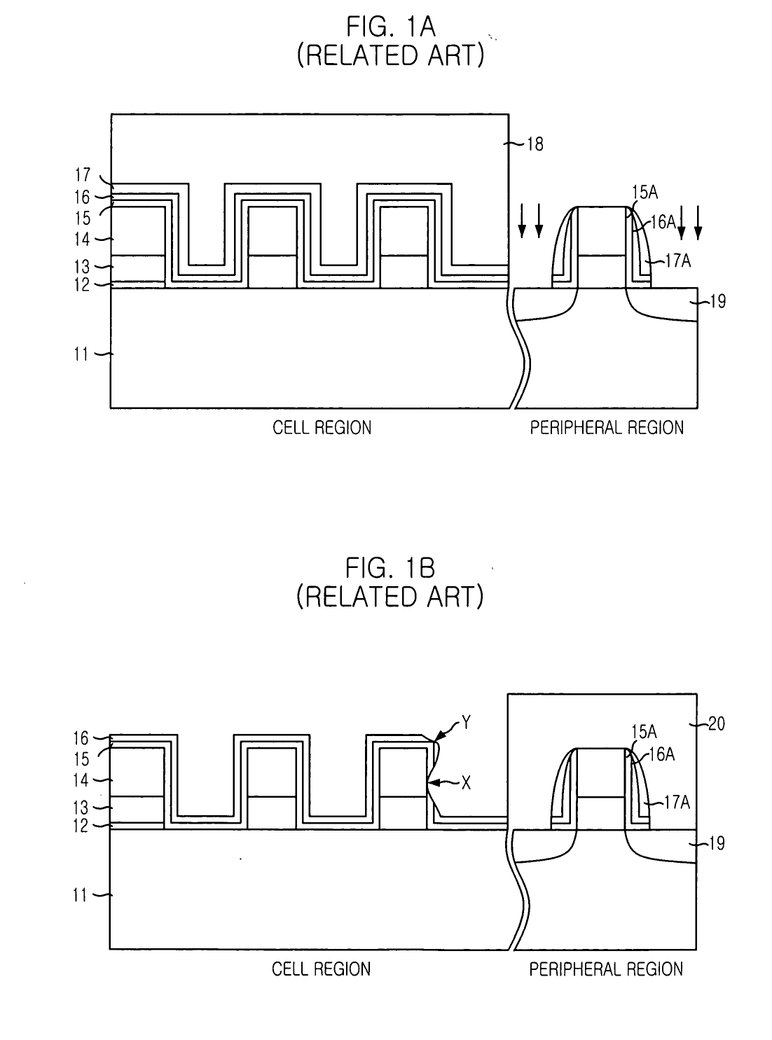

### DETAILED DESCRIPTION OF THE INVENTION

A method for fabricating a semiconductor device in accordance with specific embodiments of the present invention will be described in detail with reference to the accompanying drawings.

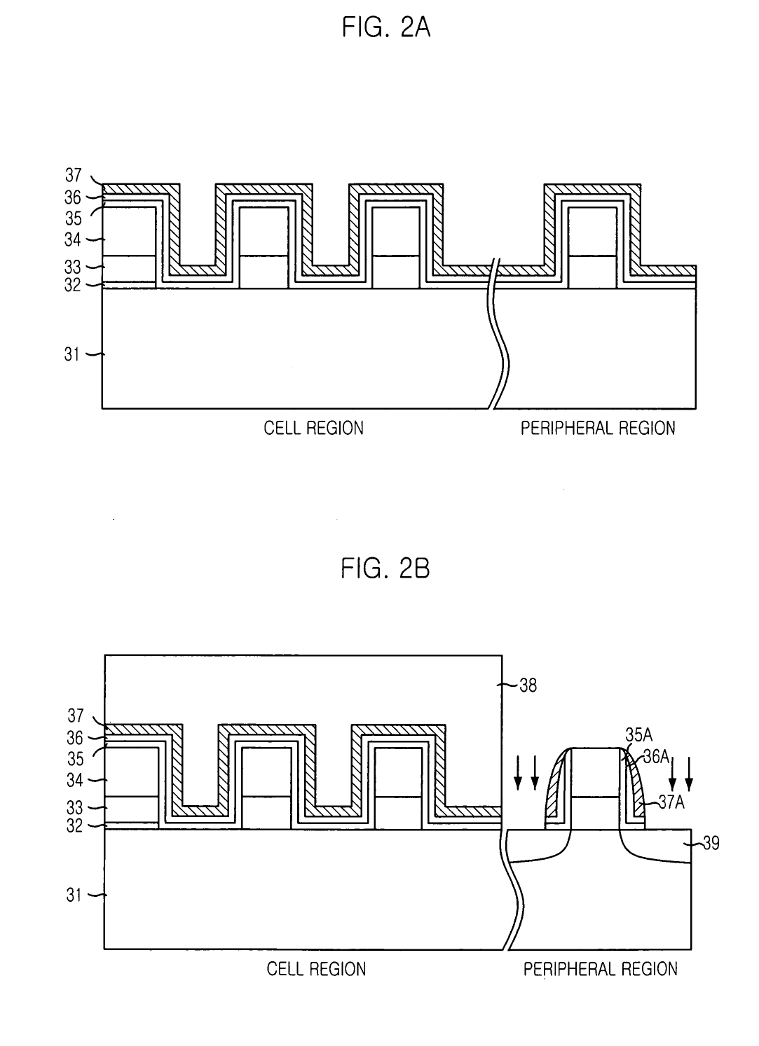

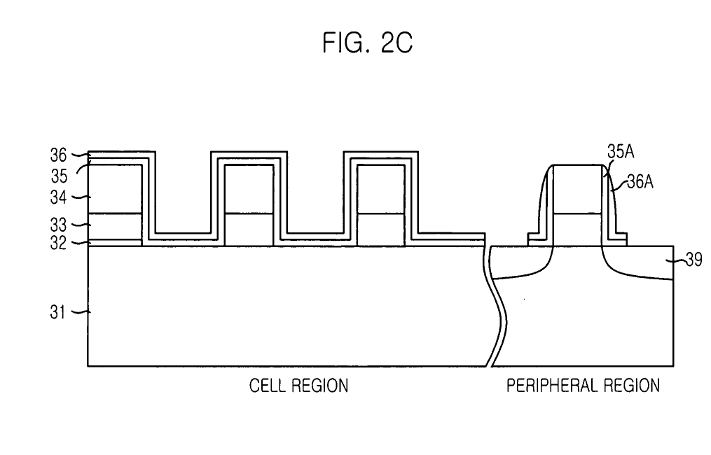

FIGS. 2A to 2C are cross-sectional views illustrating a method for fabricating a semiconductor device in accordance with a specific embodiment of the present invention.

As shown in FIG. 2A, a gate oxide layer 32 is formed over a substrate 31, wherein the substrate 31 is defined into a cell region and a peripheral region. A gate electrode 33 and a gate hard mask 34 are formed over the gate oxide layer 32, and then a gate patterning process is performed to form a plurality of gate lines. Herein, the gate lines are formed in both the cell region and the peripheral region.

Subsequently, an oxide-based layer 35 and a nitride-based layer 36 are sequentially formed over the substrate 31 and the gate lines. Then, an amorphous carbon (hereinafter “a-carbon”) layer 37 is formed over the nitride-based layer 36.

At this time, the oxide-based layer 35 includes silicon oxide and is used as a buffer layer for reducing stress applied to the substrate 31, wherein the stress is generated while forming the nitride-based layer 36 over the substrate 31. Also, the nitride-based layer 36 includes silicon nitride and is formed to provide insulation between the gate lines and a contact plug. The a-carbon layer 37 is formed to function substantially identical to a generally used second silicon oxide layer (i.e., the barrier function).

Furthermore, the oxide-based layer 35 is formed in a thickness ranging from approximately 50 Å to approximately 200 Å; the nitride-based layer 36 is formed in a thickness ranging from approximately 50 Å to approximately 200 Å; and the a-carbon layer 37 is formed in a thickness ranging from approximately 300 Å to approximately 500 Å.

As shown in FIG. 2B, a photoresist layer is formed over the a-carbon layer 37, and then a photo-exposure and developing process is performed to pattern the photoresist layer to thereby form a mask layer 38 opening the peripheral region. Herein, the mask layer 38 is formed in a manner to cover the entire cell region and open the peripheral region. Such mask layer 38 functions as a mask layer for forming spacers on sidewalls of the gate line in the peripheral region.

Portions of the a-carbon layer 37, the nitride-based layer 36, and the oxide-based layer 35 in the peripheral region are etched by employing an anisotropic etching method using the mask layer 38 as an etch mask, to form triple-layered gate spacers on the sidewalls of the gate line in the peripheral region. Herein, each of the triple-layered gate spacers includes L-shaped spacers which include a patterned oxide-based layer 35A contacting the sidewall of the gate line in the peripheral region and a patterned nitride-based layer 36A, and a dome-type spacer which includes a patterned a-carbon layer 37A.

An ion implantation process using the triple-layered gate spacers and the mask layer 38 as an ion implantation mask is performed to form source/drain regions 39 in the peripheral region.

As shown in FIG. 2C, the mask layer 38 covering the cell region is removed by employing an isotropic dry etching method. At this time, the a-carbon layer 37 is removed simultaneously with the mask layer 38. Herein, the isotropic dry etching method uses a downstream-type plasma, that is, an oxygen (O₂)-based plasma. At this time, all of the a-carbon layer 37 is removed because the a-carbon layer 37 has no selectivity to the photoresist layer used as the mask layer 38 during the dry etching process.

Consequently, because the remaining a-carbon layer 37 is simultaneously removed while removing the mask layer 38, a mask and a wet etching process generally needed during a cell region opening process are often not necessary. Furthermore, because the a-carbon layer 37 is not removed by the wet etching process, the nitride-based layer 36 remaining in the cell region can be protected from being damaged.

Moreover, the patterned a-carbon layer 37A composing the gate spacers in the peripheral region are also simulataneously removed while removing the mask layer 38. Because the patterned a-carbon layer 37A had already been used as the ion implantation barrier, limitations generally do not arise with respect to device operation after the removal of the patterned a-carbon layer 37A during the subsequent process. If necessary later on, insulation layers may be additionally formed over portions where the patterned a-carbon layer 37A is removed.

In accordance with the specific embodiments of the present invention, by forming the a-carbon layer to serve as the barrier against the ion implantation in the peripheral region after the gates are formed, and simultaneously removing the mask layer and the a-carbon layer formed in the cell region during the dry etching process, the additional wet etching process may become unnecessary. Thus, the entire process can be simplified.

Furthermore, bridges between the gate lines and the contact plugs can be reduced because the wet etching process is abridged, and thus, the nitride-based layer formed to provide insulation between the gate lines and the contact plugs can be protected from being damaged according to the specific embodiments of the present invention.

The present application contains subject matter related to the Korean patent application No. KR 2005-132569, filed in the Korean Patent Office on Dec. 28, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of gate lines over a substrate, wherein the substrate is defined into a cell region and a peripheral region;
forming a gate spacer layer over the gate lines, the gate spacer layer including a buffer layer, an insulation layer, and a barrier layer;
forming a mask pattern over the barrier layer in a manner to cover the cell region and open the peripheral region;
performing an anisotropic etching method on the gate spacer layer using the mask pattern as an etch mask to form gate spacers on sidewalls of the gate lines in the peripheral region;
performing an ion implantation process to form source/drain regions in the peripheral region; and
simultaneously removing the mask pattern and the barrier layer.

2. The method of claim 1, wherein the forming of the mask pattern and the forming of the barrier layer comprises using a material which can be simultaneously etched by a plasma.

3. The method of claim 2, wherein the simultaneous removing of the mask pattern and the barrier layer comprises performing an isotropic dry etching process using a downstream-type plasma.

4. The method of claim 3, wherein the performing of the isotropic dry etching process comprises using an oxygen (O₂) plasma.

5. The method of claim 4, wherein the forming of the barrier layer comprises including an amorphous carbon layer.

6. The method of claim 5, wherein the amorphous carbon layer is formed in a thickness ranging from approximately 300 Å to approximately 500 Å.

7. The method of claim 1, wherein the barrier layer serves a role as a barrier against the ion implantation.

8. The method of claim 1, wherein the forming of the mask pattern comprises employing a photoresist layer.

9. The method of claim 1, wherein the forming of the buffer layer comprises using silicon oxide, and the forming of the insulation layer for providing insulation between the gate lines and contacts comprises using silicon nitride.

10. The method of claim 1, wherein the forming of the gate spacer layer comprises forming the buffer layer, the insulation layer, and the barrier layer in sequential order.

11. A method for fabricating a semiconductor device, comprising:
forming a plurality of gate lines over a substrate, wherein the substrate is defined into a cell region and a peripheral region;
forming a silicon oxide layer, a silicon nitride layer, and an amorphous carbon layer over the gate lines;
forming a photoresist pattern over the amorphous carbon layer in a manner to cover the cell region and open the peripheral region;
etching the silicon oxide layer, the silicon nitride layer, and the amorphous carbon layer with an anisotropic etching method to form gate spacers on sidewalls of the gate lines in the peripheral region;
performing an ion implantation process to form source/drain regions in the peripheral region; and
simultaneously removing the mask pattern and the amorphous carbon layer.

12. The method of claim 11, wherein the simultaneous removing of the mask pattern and the amorphous carbon layer comprises performing an isotropic dry etching process using a downstream-type plasma.

13. The method of claim 12, wherein the performing of the isotropic dry etching process comprises using an O₂ plasma.

14. The method of claim 11, wherein the amorphous carbon layer is formed in a thickness ranging from approximately 300 Å to approximately 500 Å.

15. The method of claim 11, wherein the silicon oxide layer serves as a buffer layer, and the amorphous carbon layer serves as a barrier layer against the ion implantation.

16. The method of claim 11, wherein the forming of the silicon oxide layer, the silicon nitride layer, and the amorphous carbon layer is in sequential order.
